(19) United States
(12) Patent Application Publication
(10) Pub. No.: US 2022/0243082 A1
(43) Pub. Date: Aug. 4, 2022

(54) INK FOR AN ELECTRON INJECTION LAYER

(71) Applicant: ISORG, Limoges CEDEX 3 (FR)

(72) Inventors: Alex LHEUREUX, GRENOBLE (FR); Benjamin BOUTHINON, GRENOBLE (FR); Emeline SARACCO, GRENOBLE (FR)

(21) Appl. No.: 17/628,010

(22) PCT Filed: Jul. 8, 2020
(86) PCT No.: PCT/EP2020/069176

§ 371 Date: Jan. 18, 2022

(30) Foreign Application Priority Data
Jul. 19, 2019 (FR) FR1908248

(51) Int. Cl. C09D 11/36; C09D 11/033; C09D 11/106; C09D 11/102; H01L 27/30; H01L 51/00; H01L 51/44

(52) U.S. Cl. CPC C09D 11/36; C09D 11/033; C09D 11/106; H01L 51/441; H01L 27/307; H01L 51/0003; H01L 51/0034; C09D 11/102

(57) ABSTRACT

An ink includes a first non-aqueous solvent and a polymer selected from among a polyethylenimine, an ethoxylated polyethylenimine, a perfluoroanthracene, and one or a plurality of conjugated thiols.

The present patent application claims the priority benefit of French patent application FR19/08248, which is herein incorporated by reference.

### FIELD

The present disclosure generally concerns inks for optoelectronic components.

### BACKGROUND

Polyethylenimine (PEI) and polyethylenimine ethoxylated (PEIE) polymers are particularly used to modify the work function of electrodes in image sensors.

### SUMMARY

In certain applications, there is a need to improve solutions containing PEI or PEIE.

An embodiment provides an ink comprising a first non-aqueous solvent and a polymer selected from among a polyethylenimine, an ethoxylated polyethylenimine, a perfluoroanthracene, and one or a plurality of conjugated thiols.

According to an embodiment, the ink has anhydrous properties.

According to an embodiment, the polymer has a mass concentration in the range from 40% to 0.01%, for example, from 1% to 0.01%, and preferably equal to approximately 0.4%.

According to an embodiment, the polymer has a molar mass in the range from 20 kg/mol to 200 kg/mol, for example, from 70 kg/mol to 110 kg/mol, and preferably equal to 90 kg/mol.

According to an embodiment, the first solvent is selected among chlorinated solvents such as chloroform, dichloromethane, 1,2-dichloroethane, 1,1,2-trichloroethane, chlorobenzene, and o-dichlorobenzene, ether-based solvents such as tetrahydrofuran, methyltetrahydrofuran, dimethyltetrahydrofuran, dioxane, and anisole, aromatic hydrocarbon solvents such as toluene, o-xylene, m-xylene, p-xylene, benzaldehyde, tetralin (1,2,3,4-tetrahydronaphthalene), and 1,3-dimethoxybenzene, aliphatic hydrocarbon solvents such as cyclohexane, methylcyclohexane, trimethylcyclohexane, n-pentane, n-hexane, n-heptane, n-octane, n-nonane, and n-decane, ketone solvents such as acetone, methylethylketone, cyclohexanone, methylhexanone, benzophenone, and acetophenone, ester solvents such as ethyl acetate, butyl acetate, cellosolve ethyl acetate, methyl benzoate, benzyl phenyl acetate, and phenyl acetate, polyhydric alcohols and their derivatives such as ethylene glycol, monobutyl ether ethylene glycol, monoethyl ether ethylene glycol, monomethyl ether ethylene glycol, methyl glycol, dimethoxyethane, propylene glycol, diethoxymethane, triethyleneglycol monoethylether, glycerol, and 1,2-hexanediol, alcoholic solvents such as methanol, ethanol, propanol, isopropanol, and cyclohexanol, sulfoxide solvents such as dimethylsulfoxide, and amide solvents such as N-methyl-2-pyrrolidone, and N, N-dimethylformamide or a mixture of at least two of these solvents.

An embodiment provides an ink manufacturing method comprising the steps of:
adding a polymer into a first non-aqueous solvent;
adding a first hygroscopic salt; and
filtering.

Another embodiment provides an ink manufacturing method, comprising the steps of:
adding a polymer into a first non-aqueous solvent;
adding a molecular sieve; and
filtering.

An embodiment provides an electrode treatment method comprising the steps of:
adding a second salt to an ink;
depositing the ink at the surface of an electrode;
annealing; and
rinsing with a third aqueous solvent.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 shows in views (A) and (B), in the form of block diagrams, two ink manufacturing methods;

FIG. 2 shows, in the form of a block diagram, an implementation mode of a method of forming an ink monolayer at the surface of an electrode; and

FIG. 3 shows a partial simplified cross-section view of an embodiment of a user interface device having transparent electrodes.

### DESCRIPTION OF THE EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the present description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., unless specified otherwise, it is referred to the orientation of the drawings.

Unless specified otherwise, the expressions “around”, “approximately”, “substantially” and “in the order of” signify within 10%, and preferably within 5%.

Unless specified otherwise, the concentrations of polymers or of any other element are expressed in % and refer to mass concentrations (polymer mass/total mass).

The molar masses of the polymers are for example measured by gel permeation chromatography (GPC) particularly coupled to a light scattering detector. This technique comprises separating the molecules, here of the polymers, according to their size by pumping them into different columns. The light scattered at a very small angle enables to know the weight average molecular mass. The molar masses used in the present disclosure are weight average molar masses.

Unless specified otherwise, the expression “anhydrous” to qualify a solvent or a formulation means that the quantity of remaining water is smaller than approximately 20 ppm and preferably smaller than approximately 10 ppm.

Water traces in a solvent or a solution may be assayed and quantified according to the Karl Fischer method. This method is based on the Karl Fischer reagent, particularly containing diiodine (I₂). The Fischer reagent is introduced in a known quantity. Each mole of water consumes one mole of Fischer reagent diiodine. The detection of the equivalence point (the quantity of diiodine is equal to the quantity of water present in the solution) is performed by colorimetry. It is possible to determine the titration endpoints by electro-analytic methods such as the dual-electrode amperometric detection technique.

The PEI and PEIE polymers are generally available in water-containing solutions or are associated with aqueous solvents. Such aqueous solutions are not adapted to microelectronics applications, particularly to CMOS technologies.

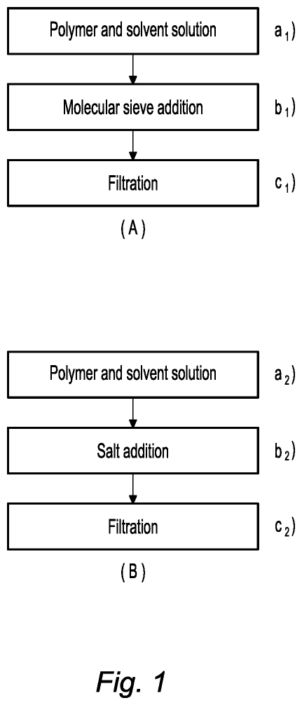

FIG. 1 shows in views (A) and (B), in the form of block diagrams, two ink manufacturing methods.

The manufacturing method illustrated in view (A) of FIG. 1 comprises three steps. The steps comprise:

a) placing in contact a polymer and a first non-aqueous solvent (block a1, Polymer and solvent solution);

b) adding a molecular sieve and mixing the assembly (block b1, Molecular sieve addition); and

c) filtering to remove the molecular sieve (block c1, Filtration).

The manufacturing method illustrated in view (B) of FIG. 1 comprises three steps. The steps comprise:

a) placing in contact a polymer and a first non-aqueous solvent (block a2, Polymer and solvent solution);

b) adding a first salt and mixing the assembly (block b2, Salt addition); and

c) filtering to remove the first salt (block c2, Filtration).

The first solvent used in the ink composition is preferably a solvent capable of uniformly dissolving or dispersing solid components in the ink composition.

Examples of first solvents comprise chlorinated solvents such as chloroform, dichloromethane, 1,2-dichloroethane, 1,1,2-trichloroethane, chlorobenzene, and o-dichlorobenzene, ether-based solvents such as tetrahydrofuran, methyltetrahydrofuran, dimethyltetrahydrofuran, dioxane, and anisole, aromatic hydrocarbon solvents such as toluene, o-xylene, m-xylene, p-xylene, benzaldehyde, tetralin (1,2,3,4-tetrahydronaphthalene), and 1,3-dimethoxybenzene, aliphatic hydrocarbon solvents such as cyclohexane, methylcyclohexane, trimethylcyclohexane, n-pentane, n-hexane, n-heptane, n-octane, n-nonane, and n-decane, ketone solvents such as acetone, methylethylketone, cyclohexanone, methylhexanone, benzophenone, and acetophenone, ester solvents such as ethyl acetate, butyl acetate, cellosolve ethyl acetate, methyl benzoate, benzyl phenyl acetate, and phenyl acetate, polyhydric alcohols and their derivatives such as ethylene glycol, monobutyl ether ethylene glycol, monoethyl ether ethylene glycol, monomethyl ether ethylene glycol, methyl glycol, dimethoxyethane, propylene glycol, diethoxymethane, triethyleneglycol monoethylether, glycerol, and 1,2-hexanediol, alcoholic solvents such as methanol, ethanol, propanol, isopropanol, and cyclohexanol, sulfoxide solvents such as dimethylsulfoxide, and amide solvents such as N-methyl-2-pyrrolidone, and N, N-dimethylformamide.

The solvents are used alone or in combination of two or more.

The polymer is selected among a polyethylenimine (PEI), an ethoxylated polyethylenimine (PEIE), a conjugated thiol, or a perfluoroanthracene.

The polymer has a molar mass in the range from 20,000 g/mol to 200,000 g/mol, for example, from 70,000 g/mol to 110,000 g/mol, and preferably equal to approximately 90,000 g/mol.

As an example, the polymer and first solvent formulation is polyethylenimine, with:
chloroform, and/or
dichloromethane, and/or
1,2-dichloroethane, and/or
1,1,2-dichloroethane, and/or
chlorobenzene, and/or
o-dichlorobenzene, and/or
tetrahydrofuran, and/or
methyltetrahydrofuran, and/or
dimethyltetrahydrofuran, and/or
dioxane, and/or
anisole, and/or
toluene, and/or
o-xylene, and/or
m-xylene, and/or
p-xylene, and/or
benzaldehyde, and/or
tetralin (1,2,3,4-tetrahydronaphthalene), and/or
1,3-dimethoxybenzene, and/or
cyclohexane, and/or
methylcyclohexane, and/or
trimethylcyclohexane, and/or
n-pentane, and/or
n-hexane, and/or
n-heptane, and/or
n-octane, and/or
n-nonane, and/or
n-decane, and/or
acetone, and/or
methylethylketone, and/or
cyclohexanone, and/or
methylhexanone, and/or
benzophenone, and/or
acetophenone, and/or
ethyl acetate, and/or
butyl acetate, and/or
cellosolve ethyl acetate, and/or
methyl benzoate, and/or
benzyl phenyl acetate, and/or
phenyl acetate, and/or
ethylene glycol, and/or
monobutyl ether ethylene glycol, and/or
monoethyl ether ethylene glycol, and/or
monomethyl ether ethylene glycol, and/or
methyl glycol, and/or
dimethoxyethane, and/or
propylene glycol, and/or
diethoxymethane, and/or
monoethylether, and/or
triethyleneglycol, and/or
glycerol, and/or
1,2-hexanediol, and/or
methanol, and/or
ethanol, and/or
propanol, and/or
isopropanol, and/or
cyclohexanol, and/or
dimethylsulfoxide, and/or
N-methyl-2-pyrrolidone, and/or
N, N-dimethylformamide.

According to other examples, the polymer and first solvent formulation is ethoxylated polyethylenimine, with:
chloroform, and/or
dichloromethane, and/or
1,2-dichloroethane, and/or
1,1,2-dichloroethane, and/or
chlorobenzene, and/or
o-dichlorobenzene, and/or
tetrahydrofuran, and/or
methyltetrahydrofuran, and/or
dimethyltetrahydrofuran, and/or
dioxane, and/or
anisole, and/or
toluene, and/or
o-xylene, and/or
m-xylene, and/or
p-xylene, and/or
benzaldehyde, and/or
tetralin (1,2,3,4-tetrahydronaphthalene), and/or
1,3-dimethoxybenzene, and/or
cyclohexane, and/or
methylcyclohexane, and/or
trimethylcyclohexane, and/or
n-pentane, and/or
n-hexane, and/or
n-heptane, and/or
n-octane, and/or
n-nonane, and/or
n-decane, and/or
acetone, and/or
methylethylketone, and/or
cyclohexane, and/or
methylhexanone, and/or
benzophenone, and/or
acetophenone, and/or
ethyl acetate, and/or
butyl acetate, and/or
cellosolve ethyl acetate, and/or
methyl benzoate, and/or
benzyl phenyl acetate, and/or
phenyl acetate, and/or
ethylene glycol, and/or
monobutyl ether ethylene glycol, and/or
monoethyl ether ethylene glycol, and/or
monomethyl ether ethylene glycol, and/or
methyl glycol, and/or
dimethoxyethane, and/or
propylene glycol, and/or
diethoxymethane, and/or
monoethylether, and/or
triethylene glycol, and/or
glycerol, and/or
1,2-hexanediol, and/or
methanol, and/or
ethanol, and/or
propanol, and/or
isopropanol, and/or
cyclohexanol, and/or
dimethylsulfoxide, and/or
N-methyl-2-pyrrolidone, and/or
N, N-dimethylformamide.

According to other examples, the polymer and first solvent is perfluoroanthracene with:
chloroform, and/or
dichloromethane, and/or
1,2-dichloroethane, and/or
1,1,2-dichloroethane, and/or
chlorobenzene, and/or
o-dichlorobenzene, and/or
tetrahydrofuran, and/or
methyltetrahydrofuran, and/or
dimethyltetrahydrofuran, and/or
dioxane, and/or
anisole, and/or
toluene, and/or
o-xylene, and/or
m-xylene, and/or
p-xylene, and/or
benzaldehyde, and/or
tetralin (1,2,3,4-tetrahydronaphthalene), and/or
1,3-dimethoxybenzene, and/or
cyclohexane, and/or
methylcyclohexane, and/or
trimethylcyclohexane, and/or
n-pentane, and/or
n-hexane, and/or
n-heptane, and/or
n-octane, and/or
n-nonane, and/or
n-decane, and/or
acetone, and/or
methylethylketone, and/or
cyclohexane, and/or
methylhexanone, and/or
benzophenone, and/or
acetophenone, and/or
ethyl acetate, and/or
butyl acetate, and/or
cellosolve ethyl acetate, and/or
methyl benzoate, and/or
benzyl phenyl acetate, and/or
phenyl acetate, and/or
ethylene glycol, and/or
monobutyl ether ethylene glycol, and/or
monoethyl ether ethylene glycol, and/or
monomethyl ether ethylene glycol, and/or
methyl glycol, and/or
dimethoxyethane, and/or
propylene glycol, and/or
diethoxymethane, and/or
monoethylether, and/or
triethyleneglycol, and/or
glycerol, and/or
1,2-hexanediol, and/or
methanol, and/or
ethanol, and/or
propanol, and/or
isopropanol, and/or
cyclohexanol, and/or
dimethylsulfoxide, and/or
N-methyl-2-pyrrolidone, and/or
N, N-dimethylformamide.

According to other examples, the polymer and first solvent formulation is one or a plurality of conjugated thiols, with:
chloroform, and/or
dichloromethane, and/or
1,2-dichloroethane, and/or
1,1,2-dichloroethane, and/or
chlorobenzene, and/or
o-dichlorobenzene, and/or
tetrahydrofuran, and/or
methyltetrahydrofuran, and/or
dimethyltetrahydrofuran, and/or
dioxane, and/or
anisole, and/or
toluene, and/or
o-xylene, and/or
m-xylene, and/or
p-xylene, and/or
benzaldehyde, and/or
tetralin (1,2,3,4-tetrahydronaphthalene), and/or
1,3-dimethoxybenzene, and/or
cyclohexane, and/or
methylcyclohexane, and/or
trimethylcyclohexane, and/or
n-pentane, and/or
n-hexane, and/or
n-heptane, and/or
n-octane, and/or
n-nonane, and/or
n-decane, and/or
acetone, and/or
methylethylketone, and/or
cyclohexane, and/or
methylhexanone, and/or
benzophenone, and/or
acetophenone, and/or
ethyl acetate, and/or
butyl acetate, and/or
cellosolve ethyl acetate, and/or
methyl benzoate, and/or
benzyl phenyl acetate, and/or
phenyl acetate, and/or
ethylene glycol, and/or
monobutyl ether ethylene glycol, and/or
monoethyl ether ethylene glycol, and/or
monomethyl ether ethylene glycol, and/or
methyl glycol, and/or
dimethoxyethane, and/or
propylene glycol, and/or
diethoxymethane, and/or
monoethylether, and/or
triethyleneglycol, and/or
glycerol, and/or
1,2-hexanediol, and/or
methanol, and/or
ethanol, and/or
propanol, and/or
isopropanol, and/or
cyclohexanol, and/or
dimethylsulfoxide, and/or
N-methyl-2-pyrrolidone, and/or
N, N-dimethylformamide.

According to other examples, the polymer and first solvent formulation is chloroform, with: polyethylenimine, and/or ethoxylated polyethylenimine, and/or perfluoroanthracene, and/or one or a plurality of conjugated thiols.

According to other examples, the polymer and first solvent formulation is dichloromethane, with: polyethylenimine, and/or ethoxylated polyethylenimine, and/or perfluoroanthracene, and/or one or a plurality of conjugated thiols.

According to other examples, the polymer and first solvent formulation is 1,2-dicholoroethane with: polyethylenimine, and/or ethoxylated polyethylenimine, and/or perfluoroanthracene, and/or one or a plurality of conjugated thiols.

According to other examples, the polymer and first solvent formulation is 1,1,2-trichloroethane with: polyethylenimine, and/or ethoxylated polyethylenimine, and/or perfluoroanthracene, and/or one or a plurality of conjugated thiols.

According to other examples, the polymer and first solvent formulation is chlorobenzene, with: polyethylenimine, and/or ethoxylated polyethylenimine, and/or perfluoroanthracene, and/or one or a plurality of conjugated thiols.

According to other examples, the polymer and first solvent formulation is o-dichlorobenzene, with: polyethylenimine, and/or ethoxylated polyethylenimine, and/or perfluoroanthracene, and/or one or a plurality of conjugated thiols.

According to other examples, the polymer and first solvent formulation is tetrahydrofuran with: polyethylenimine, and/or ethoxylated polyethylenimine, and/or perfluoroanthracene, and/or one or a plurality of conjugated thiols.

According to other examples, the polymer and first solvent formulation is methyltetrahydrofuran with: polyethylenimine, and/or ethoxylated polyethylenimine, and/or perfluoroanthracene, and/or one or a plurality of conjugated thiols.

According to other examples, the polymer and first solvent formulation is dimethyltetrahydrofuran with: polyethylenimine, and/or ethoxylated polyethylenimine, and/or perfluoroanthracene, and/or one or a plurality of conjugated thiols.

According to other examples, the polymer and first solvent formulation is dioxane with: polyethylenimine, and/or ethoxylated polyethylenimine, and/or perfluoroanthracene, and/or one or a plurality of conjugated thiols.

According to other examples, the polymer and first solvent formulation is anisole with: polyethylenimine, and/or ethoxylated polyethylenimine, and/or perfluoroanthracene, and/or one or a plurality of conjugated thiols.

According to other examples, the polymer and first solvent formulation is toluene with: polyethylenimine, and/or ethoxylated polyethylenimine, and/or perfluoroanthracene, and/or one or a plurality of conjugated thiols.

According to other examples, the polymer and first solvent formulation is o-xylene with: polyethylenimine, and/or ethoxylated polyethylenimine, and/or perfluoroanthracene, and/or one or a plurality of conjugated thiols.

According to other examples, the polymer and first solvent formulation is m-xylene with: polyethylenimine, and/or ethoxylated polyethylenimine, and/or perfluoroanthracene, and/or one or a plurality of conjugated thiols.

According to other examples, the polymer and first solvent formulation is p-xylene with: polyethylenimine, and/or ethoxylated polyethylenimine, and/or perfluoroanthracene, and/or one or a plurality of conjugated thiols.

According to other examples, the polymer and first solvent formulation is benzaldehyde with: polyethylenimine, and/or ethoxylated polyethylenimine, and/or perfluoroanthracene, and/or one or a plurality of conjugated thiols.

According to other examples, the polymer and first solvent formulation is tetralin (1,2,3,4-tetrahydronaphtalene) with: polyethylenimine, and/or ethoxylated polyethylenimine, and/or perfluoroanthracene, and/or one or a plurality of conjugated thiols.

According to other examples, the polymer and first solvent formulation is 1,3-dimethoxybenzene with: polyethylenimine, and/or ethoxylated polyethylenimine, and/or perfluoroanthracene, and/or one or a plurality of conjugated thiols.

According to other examples, the polymer and first solvent formulation is cyclohexane with: polyethylenimine, and/or ethoxylated polyethylenimine, and/or perfluoroanthracene, and/or one or a plurality of conjugated thiols.

According to other examples, the polymer and first solvent formulation is methylcyclohexane with: polyethylenimine, and/or ethoxylated polyethylenimine, and/or perfluoroanthracene, and/or one or a plurality of conjugated thiols.

According to other examples, the polymer and first solvent formulation is trimethylcyclohexane with: polyethylenimine, and/or ethoxylated polyethylenimine, and/or perfluoroanthracene, and/or one or a plurality of conjugated thiols.

According to other examples, the polymer and first solvent formulation is n-pentane with: polyethylenimine, and/or ethoxylated polyethylenimine, and/or perfluoroanthracene, and/or one or a plurality of conjugated thiols.

According to other examples, the polymer and first solvent formulation is n-hexane with: polyethylenimine, and/or ethoxylated polyethylenimine, and/or perfluoroanthracene, and/or one or a plurality of conjugated thiols.

According to other examples, the polymer and first solvent formulation is n-heptane with: polyethylenimine, and/or ethoxylated polyethylenimine, and/or perfluoroanthracene, and/or one or a plurality of conjugated thiols.

According to other examples, the polymer and first solvent formulation is n-octane with: polyethylenimine, and/or ethoxylated polyethylenimine, and/or perfluoroanthracene, and/or one or a plurality of conjugated thiols.

According to other examples, the polymer and first solvent formulation is n-nonane with: polyethylenimine, and/or ethoxylated polyethylenimine, and/or perfluoroanthracene, and/or one or a plurality of conjugated thiols.

According to other examples, the polymer and first solvent formulation is n-decane with: polyethylenimine, and/or ethoxylated polyethylenimine, and/or perfluoroanthracene, and/or one or a plurality of conjugated thiols.

According to other examples, the polymer and first solvent formulation is acetone with: polyethylenimine, and/or ethoxylated polyethylenimine, and/or perfluoroanthracene, and/or one or a plurality of conjugated thiols.

According to other examples, the polymer and first solvent formulation is methylethylketone with: polyethylenimine, and/or ethoxylated polyethylenimine, and/or perfluoroanthracene, and/or one or a plurality of conjugated thiols.

According to other examples, the polymer and first solvent formulation is cyclohexanone with: polyethylenimine, and/or ethoxylated polyethylenimine, and/or perfluoroanthracene, and/or one or a plurality of conjugated thiols.

According to other examples, the polymer and first solvent formulation is methylhexanone with: polyethylenimine, and/or ethoxylated polyethylenimine, and/or perfluoroanthracene, and/or one or a plurality of conjugated thiols.

According to other examples, the polymer and first solvent formulation is benzophenone with: polyethylenimine, and/or ethoxylated polyethylenimine, and/or perfluoroanthracene, and/or one or a plurality of conjugated thiols.

According to other examples, the polymer and first solvent formulation is acetophenone with: polyethylenimine, and/or ethoxylated polyethylenimine, and/or perfluoroanthracene, and/or one or a plurality of conjugated thiols.

According to other examples, the polymer and first solvent formulation is ethyl acetate with: polyethylenimine, and/or ethoxylated polyethylenimine, and/or perfluoroanthracene, and/or one or a plurality of conjugated thiols.

According to other examples, the polymer and first solvent formulation is butyl acetate with: polyethylenimine, and/or ethoxylated polyethylenimine, and/or perfluoroanthracene, and/or one or a plurality of conjugated thiols.

According to other examples, the polymer and first solvent formulation is cellosolve ethyl acetate with: polyethylenimine, and/or ethoxylated polyethylenimine, and/or perfluoroanthracene, and/or one or a plurality of conjugated thiols.

According to other examples, the polymer and first solvent formulation is methyl benzoate with: polyethylenimine, and/or ethoxylated polyethylenimine, and/or perfluoroanthracene, and/or one or a plurality of conjugated thiols.

According to other examples, the polymer and first solvent formulation is phenyl benzyl acetate with: polyethylenimine, and/or ethoxylated polyethylenimine, and/or perfluoroanthracene, and/or one or a plurality of conjugated thiols.

According to other examples, the polymer and first solvent formulation is phenyl acetate with: polyethylenimine, and/or ethoxylated polyethylenimine, and/or perfluoroanthracene, and/or one or a plurality of conjugated thiols.

According to other examples, the polymer and first solvent formulation is ethylene glycol with: polyethylenimine, and/or ethoxylated polyethylenimine, and/or perfluoroanthracene, and/or one or a plurality of conjugated thiols.

According to other examples, the polymer and first solvent formulation is monobutyl ether ethylene glycol with: polyethylenimine, and/or ethoxylated polyethylenimine, and/or perfluoroanthracene, and/or one or a plurality of conjugated thiols.

According to other examples, the polymer and first solvent formulation is monoethyl ether ethylene glycol with: polyethylenimine, and/or ethoxylated polyethylenimine, and/or perfluoroanthracene, and/or one or a plurality of conjugated thiols.

According to other examples, the polymer and first solvent formulation is monomethyl ether ethylene glycol with: polyethylenimine, and/or ethoxylated polyethylenimine, and/or perfluoroanthracene, and/or one or a plurality of conjugated thiols.

According to other examples, the polymer and first solvent formulation is methyl glycol with: polyethylenimine, and/or ethoxylated polyethylenimine, and/or perfluoroanthracene, and/or one or a plurality of conjugated thiols.

According to other examples, the polymer and first solvent formulation is dimethoxyethane with: polyethylenimine, and/or ethoxylated polyethylenimine, and/or perfluoroanthracene, and/or one or a plurality of conjugated thiols.

According to other examples, the polymer and first solvent formulation is propylene glycol with: polyethylenimine, and/or ethoxylated polyethylenimine, and/or perfluoroanthracene, and/or one or a plurality of conjugated thiols.

According to other examples, the polymer and first solvent formulation is diethoxymethane with: polyethylenimine, and/or ethoxylated polyethylenimine, and/or perfluoroanthracene, and/or one or a plurality of conjugated thiols.

According to other examples, the polymer and first solvent formulation is monoethylether with: polyethylenimine, and/or ethoxylated polyethylenimine, and/or perfluoroanthracene, and/or one or a plurality of conjugated thiols.

According to other examples, the polymer and first solvent formulation is triethyleneglycol with: polyethylenimine, and/or ethoxylated polyethylenimine, and/or perfluoroanthracene, and/or one or a plurality of conjugated thiols.

According to other examples, the polymer and first solvent formulation is glycerol with: polyethylenimine, and/or ethoxylated polyethylenimine, and/or perfluoroanthracene, and/or one or a plurality of conjugated thiols.

According to other examples, the polymer and first solvent formulation is 1,2-hexanediol with: polyethylenimine, and/or ethoxylated polyethylenimine, and/or perfluoroanthracene, and/or one or a plurality of conjugated thiols.

According to other examples, the polymer and first solvent formulation is methanol with: polyethylenimine, and/or ethoxylated polyethylenimine, and/or perfluoroanthracene, and/or one or a plurality of conjugated thiols.

According to other examples, the polymer and first solvent formulation is ethanol with: polyethylenimine, and/or ethoxylated polyethylenimine, and/or perfluoroanthracene, and/or one or a plurality of conjugated thiols.

According to other examples, the polymer and first solvent formulation is propanol with: polyethylenimine, and/or ethoxylated polyethylenimine, and/or perfluoroanthracene, and/or one or a plurality of conjugated thiols.

According to other examples, the polymer and first solvent formulation is isopropanol with: polyethylenimine, and/or ethoxylated polyethylenimine, and/or perfluoroanthracene, and/or one or a plurality of conjugated thiols.

According to other examples, the polymer and first solvent formulation is cyclohexanol with: polyethylenimine, and/or ethoxylated polyethylenimine, and/or perfluoroanthracene, and/or one or a plurality of conjugated thiols.

According to other examples, the polymer and first solvent formulation is dimethylsulfoxide with: polyethylenimine, and/or ethoxylated polyethylenimine, and/or perfluoroanthracene, and/or one or a plurality of conjugated thiols.

According to other examples, the polymer and first solvent formulation is N-methyl-2-pyrrolidone with: polyethylenimine, and/or ethoxylated polyethylenimine, and/or perfluoroanthracene, and/or one or a plurality of conjugated thiols.

According to other examples, the polymer and first solvent formulation is N,N-dimethylformamide with: polyethylenimine, and/or ethoxylated polyethylenimine, and/or perfluoroanthracene, and/or one or a plurality of conjugated thiols.

In the present embodiment, the molecular sieve is an aluminosilicate which has the property of adsorbing water molecules. Generally designed in the form of balls, molecular sieves have sieve openings from approximately 0.3 nm to 1 nm. In the present case, it is preferred to use a grade-3A molecular sieve having sieve openings of approximately 0.3 nm or a grade-4A molecular sieve having pore openings of approximately 0.4 nm.

The use of the molecular sieve comprises adding it to the solvent or to the solution to be made anhydrous, letting it operate for approximately 48 hours, and then filtering it. The molecular sieve is introduced at a concentration of approximately 200 g/L.

According to an embodiment, the polymer has a final concentration in the first solvent in the range from 40% to 0.01%, for example, from 1% to 0.01% and preferably equal to approximately 0.4%.

The first salt is hygroscopic and is selected among anhydrous magnesium sulfate MgSO₄, anhydrous sodium sulfate Na₂SO₄, anhydrous calcium chloride CaCl₂), sodium hydride NaH, or anhydrous potassium carbonate K₂CO₃, preferably magnesium sulfate. The first salt is introduced at a concentration in the range from approximately 10 to 100 g/L, preferably from 40 to 60 g/L, preferably in the order of 50 g/L.

The salt settles as long as there is water in the solution. As soon as the water is totally removed from the medium, the salt becomes in suspension. The filtering is performed once the salt is in suspension.

According to another embodiment, the polymer is initially in solution in a second solvent, which is aqueous. The three ink manufacturing steps (according to the embodiment illustrated in view (A) in FIG. 1 or according to the embodiment illustrated in view (B) in FIG. 1) are thus preceded by a step of evaporation of the second solvent. The second solvent is aqueous and mainly contains water.

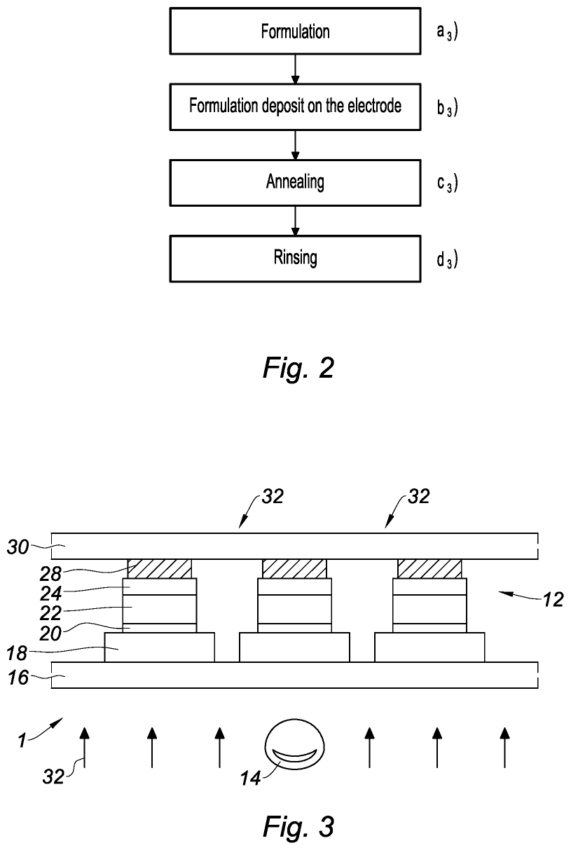

FIG. 2 shows, in the form of a block diagram, an implementation mode of a method of forming an ink monolayer at the surface of an electrode.

The embodiment illustrated in FIG. 2 comprises four steps. The steps comprise:

a) adding a second salt in the ink having had its formulation previously described in relation with FIG. 1 (block a3, Formulation);

b) depositing the ink on an electrode surface (block b3, formulation deposit on the electrode);

c) annealing the assembly (block c3, Annealing); and d) rinsing the deposit by means of a third aqueous solvent (block d3, Rinsing).

During step b3), the polymer adsorbs, by physisorption or chemisorption according to polymers, on the surface, thus forming a first layer. The other components of the ink: the second salt, the polymer, and the first solvent deposit in successive layers. Step c3) enables to fix the polymer on the surface and to evaporate the first solvent. During step d3), the third aqueous solvent carries down the residual non-aqueous solvent and the polymer which has not been physisorbed or chemisorbed with the action of the second hygroscopic salt.

The PEIE and the PEI generate a physisorption mechanism at the electrode surface while perfluoroanthracene and the conjugated thiols generate a chemisorption mechanism.

The second salt is highly water-soluble and is selected among anhydrous magnesium sulfate MgSO₄, anhydrous sodium sulfate Na₂SO₄, anhydrous calcium chloride CaCl₂), sodium hydride NaH, or anhydrous potassium carbonate K₂CO₃, preferably magnesium sulfate. The first and second salts may be different or identical.

The second salt is introduced at a concentration in the range from approximately 10 to 100 g/L, preferably from 40 to 60 g/L, preferably in the order of 50 g/L.

According to an embodiment, the electrode is made of a metal oxide, selected from the list: zinc oxides ZnOₓ, indium-tin oxide ITO, zinc-tin oxide ZTO, zinc-aluminum oxide AzO, titanium oxides TiOₓ, molybdenum oxides MoOₓ, nickel oxides NiOₓ, chromium oxides CrOₓ, copper oxides CuOₓ, cobalt oxides CoOₓ, iron oxides FeOₓ, manganese oxides MnOₓ, or a mixture of at least two of these oxides.

According to an embodiment, the electrode is made of metal, selected from the list: gold, copper, silver, molybdenum-tantalum, molybdenum-copper.

According to an embodiment, the deposition is performed by spin coating. Such a deposition is optimal for an ink having a polymer concentration of approximately 0.4%.

According to an embodiment, the deposition is performed by dip coating. Such a deposition is optimal for an ink having a polymer concentration of approximately 0.04%.

FIG. 3 shows a partial simplified cross-section view of an embodiment of a user interface device having transparent electrodes.

Device 1 comprises an array of photon sensors, called photodetectors 12, preferably capable of detecting variations of the shadow or of the image of a driving member, for example, a finger 14. The photodetectors are formed on a substrate 16 made of a transparent or translucent dielectric, for example, of glass or plastic.

Each photodetector 12 comprises in the stack, from bottom to top:
an opaque or transparent metal electrode 18 made of:
   a TCO (Transparent Conductive Oxide) material, for example, indium tin oxide, gallium zinc oxide, tin oxide, fluorine tin oxide (FTO), zinc oxide, aluminum zinc oxide, indium cadmium oxide, titanium nitride TiN;
   of a metal, for example, gold, silver, lead, palladium, copper, nickel, tungsten, or chromium;
   of carbon, silver, or copper nanowires;
   of graphene; or
   of a mixture of two or more of these materials;
an electron injecting layer EIL 20, having the same surface area as layer 18, made up of an ink such as previously described in relation with FIG. 1, deposited according to the method described in relation with FIG. 2;
a layer 22 made of a mixture of organic semiconductor polymers, for example poly(3-hexylthiophene) or poly(3-hexylthiophene-2,5-diyl), known as P3HT, mixed with [6,6]-phenyl-C₆₁-butyric acid methyl ester (N-type semiconductor), known as PCBM;
a layer 24 made of a heavily-doped organic semiconductor material HTL (Hole Transport Layer), for example, a polymer known as PEDOT:PSS.
an electrode 28 forming a cathode common to all pixels, made up of a PEDOT:PSS type polymer or of a TCO, such as for example ITO (indium tin oxide).

The photoactive layer 22 of photodetectors 12 is here intended to be illuminated through encapsulation layer 30 and through electrode 28 and layer 24. The light radiation is schematically represented by arrows 32.

Layers 24 may be structured for example during a photolithography step, not shown herein.

Photodetector array 12 may be a passive array or an active array. For a passive array, transparent electrodes 28 may correspond to parallel rectilinear strips, and each strip may be connected to all the photodetectors 12 of a same row. For an active array, transparent electrodes 28 may correspond to a continuous layer in contact with all the photodetectors 12 of the array. As a variant, transparent electrodes 28 may be isolated from one another, photodetectors 12 being in this case independent from one another.

More generally, an ink such as previously described in relation with FIG. 1 may be deposited, according to the method described in relation with FIG. 2, on an image sensor electrode of the type described in documents FR2989483 (B11534), FR3017996 (B12733), FR3046297, FR3073648 (B16671), FR3046300, FR3065583 (B13922), FR3063596 (B16100), FR3063564 (B15702), FR3046496, FR3017994 (B12870), FR2992474, FR2980598 (B11347), FR2977080.

An advantage of the described embodiments and implementation modes is the improvement of solutions containing PEI and PEIE.

Another advantage of the described embodiments and implementation modes is the control of the thickness of the PEI or PEIE deposition on an image sensor electrode.

Various embodiments and variants have been described. Those skilled in the art will understand that certain features of these embodiments can be combined and other variants will readily occur to those skilled in the art.

Finally, the practical implementation of the described embodiments and variations is within the abilities of those skilled in the art based on the functional indications given hereabove.

1. An ink comprising a first non-aqueous solvent and a polymer selected from among a polyethylenimine, an ethoxylated polyethylenimine, a perfluoroanthracene, and one or a plurality of conjugated thiols.

2. The ink according to claim 1, having anhydrous properties.

3. The ink according to claim 1, wherein the polymer has a mass concentration in the range from 40% to 0.01%.

4. The ink according to claim 3, wherein the polymer has a mass concentration in the range from 1% to 0.01% or equal to approximately 0.4%.

5. The ink according to claim 1, wherein the polymer has a molar mass in the range from 20 kg/mol to 200 kg/mol.

6. The ink according to claim 5, wherein the polymer has a molar mass in the range from 70 kg/mol to 110 kg/mol or equal to approximately 90 kg/mol.

7. The ink according to claim 1, wherein the first solvent is selected among chlorinated solvents including chloroform, dichloromethane, 1,2-dichloroethane, 1,1,2-trichloroethane, chlorobenzene, and o-dichlorobenzene, ether-based solvents including tetrahydrofuran, methyltetrahydrofuran, dimethyltetrahydrofuran, dioxane, and anisole, aromatic hydrocarbon solvents including toluene, o-xylene, m-xylene, p-xylene, benzaldehyde, tetralin (1,2,3,4-tetrahydronaphthalene), and 1,3-dimethoxybenzene, aliphatic hydrocarbon solvents including cyclohexane, methylcyclohexane, trimethylcyclohexane, n-pentane, n-hexane, n-heptane, n-octane, n-nonane, and n-decane, ketone solvents including acetone, methylethylketone, cyclohexanone, methylhexanone, benzophenone, and acetophenone, ester solvents including ethyl acetate, butyl acetate, cellosolve ethyl acetate, methyl benzoate, benzyl phenyl acetate, and phenyl acetate, polyhydric alcohols and their derivatives including ethylene glycol, monobutyl ether ethylene glycol, monoethyl ether ethylene glycol, monomethyl ether ethylene glycol, methyl glycol, dimethoxyethane, propylene glycol, diethoxymethane, triethyleneglycol monoethylether, glycerol, and 1,2-hexanediol, alcoholic solvents including methanol, ethanol, propanol, isopropanol, and cyclohexanol, sulfoxide solvents including dimethylsulfoxide, and amide solvents including N-methyl-2-pyrrolidone and N, N-dimethylformamide or a mixture of at least two of these solvents.

8. A method of manufacturing an ink, comprising the steps of:
adding a polymer into a first non-aqueous solvent;
adding a first hygroscopic salt; and
filtering.

9. A method of manufacturing an ink, comprising the steps of:
adding a polymer into a first non-aqueous solvent;
adding a molecular sieve; and
filtering.

10. An electrode treatment method comprising the steps of:
adding a second salt to an ink, according to claim 1;
depositing the ink at the surface of an electrode;
annealing; and
rinsing with a third aqueous solvent.

11. The method of claim 8, wherein said polymer is selected from among a polyethylenimine, an ethoxylated polyethylenimine, a perfluoroanthracene, and one or a plurality of conjugated thiols.

12. The method of claim 8, wherein the polymer has a mass concentration in the range from 40% to 0.01%.

13. The method of claim 8, wherein the polymer has a mass concentration in the range from 1% to 0.01% or equal to approximately 0.4%.

14. The method of claim 8, wherein the polymer has a molar mass in the range from 20 kg/mol to 200 kg/mol.

15. The method of claim 8, wherein the first solvent is selected among chlorinated solvents including chloroform, dichloromethane, 1,2-dichloroethane, 1,1,2-trichloroethane, chlorobenzene, and o-dichlorobenzene, ether-based solvents including tetrahydrofuran, methyltetrahydrofuran, dimethyltetrahydrofuran, dioxane, and anisole, aromatic hydrocarbon solvents including toluene, o-xylene, m-xylene, p-xylene, benzaldehyde, tetralin (1,2,3,4-tetrahydronaphthalene), and 1,3-dimethoxybenzene, aliphatic hydrocarbon solvents including cyclohexane, methylcyclohexane, trimethylcyclohexane, n-pentane, n-hexane, n-heptane, n-octane, n-nonane, and n-decane, ketone solvents including acetone, methylethylketone, cyclohexanone, methylhexanone, benzophenone, and acetophenone, ester solvents including ethyl acetate, butyl acetate, cellosolve ethyl acetate, methyl benzoate, benzyl phenyl acetate, and phenyl acetate, polyhydric alcohols and their derivatives including ethylene glycol, monobutyl ether ethylene glycol, monoethyl ether ethylene glycol, monomethyl ether ethylene glycol, methyl glycol, dimethoxyethane, propylene glycol, diethoxymethane, triethyleneglycol monoethylether, glycerol, and 1,2-hexanediol, alcoholic solvents including methanol, ethanol, propanol, isopropanol, and cyclohexanol, sulfoxide solvents including dimethylsulfoxide, and amide solvents including N-methyl-2-pyrrolidone and N, N-dimethylformamide or a mixture of at least two of these solvents.

16. The method of claim 9, wherein said polymer is selected from among a polyethylenimine, an ethoxylated polyethylenimine, a perfluoroanthracene, and one or a plurality of conjugated thiols.

17. The method of claim 9, wherein the polymer has a mass concentration in the range from 40% to 0.01%.

18. The method of claim 9, wherein the polymer has a mass concentration in the range from 1% to 0.01% or equal to approximately 0.4%.

19. The method of claim 9, wherein the polymer has a molar mass in the range from 20 kg/mol to 200 kg/mol.

20. The method of claim 9, wherein the first solvent is selected among chlorinated solvents including chloroform, dichloromethane, 1,2-dichloroethane, 1,1,2-trichloroethane, chlorobenzene, and o-dichlorobenzene, ether-based solvents including tetrahydrofuran, methyltetrahydrofuran, dimethyltetrahydrofuran, dioxane, and anisole, aromatic hydrocarbon solvents including toluene, o-xylene, m-xylene, p-xylene, benzaldehyde, tetralin (1,2,3,4-tetrahydronaphthalene), and 1,3-dimethoxybenzene, aliphatic hydrocarbon solvents including cyclohexane, methylcyclohexane, trimethylcyclohexane, n-pentane, n-hexane, n-heptane, n-octane, n-nonane, and n-decane, ketone solvents including acetone, methylethylketone, cyclohexanone, methylhexanone, benzophenone, and acetophenone, ester solvents including ethyl acetate, butyl acetate, cellosolve ethyl acetate, methyl benzoate, benzyl phenyl acetate, and phenyl acetate, polyhydric alcohols and their derivatives including ethylene glycol, monobutyl ether ethylene glycol, monoethyl ether ethylene glycol, monomethyl ether ethylene glycol, methyl glycol, dimethoxyethane, propylene glycol, diethoxymethane, triethyleneglycol monoethylether, glycerol, and 1,2-hexanediol, alcoholic solvents including methanol, ethanol, propanol, isopropanol, and cyclohexanol, sulfoxide solvents including dimethylsulfoxide, and amide solvents including N-methyl-2-pyrrolidone and N, N-dimethylformamide or a mixture of at least two of these solvents.
